(19) United States
(12) Patent Application Publication
(10) Pub. No.: US 2015/0014047 A1
(43) Pub. Date: Jan. 15, 2015

(54) Method and Apparatus for Electromagnetic Interference Protection

(71) Applicant: Topcon Medical Laser Systems, Inc., Santa Clara, CA (US)

(72) Inventors: Sheldon Hutchison, Sunnyvale, CA (US); Greg Halstead, Sunnyvale, CA (US)

(21) Appl. No.: 13/940,599

(22) Filed: Jul. 12, 2013

(51) Int. Cl. H05K 9/00

(52) U.S. Cl. CPC H05K 9/009
USPC 174/350; 29/602.1

(57) ABSTRACT

A method and apparatus for EMI protection is disclosed. Particularly, the present invention is directed to an article of manufacture for electromagnetic interference shielding comprising a cylindrically-shaped sleeve constructed of a conductive fabric adapted to provide electromagnetic interference shielding by conducting at least a portion of electromagnetic radiation, wherein the cylindrically-shaped sleeve is made by rolling a piece of conductive fabric into a cylindrical shape such that opposing sides of the piece of conductive fabric are joined together resulting in the cylindrically-shaped sleeve having a seam at a junction of the opposing sides. In one embodiment, opposing sides of the piece of conductive fabric are sewn together.

### FIELD OF THE INVENTION

The present invention relates generally to electromagnetic shielding and, more particularly, to a method and apparatus for electromagnetic interference (EMI) protection to improve the effectiveness of EMI shielding.

### BACKGROUND OF THE INVENTION

The term “EMI”, as used herein, should be considered to refer generally to both electromagnetic interference and radio frequency interference (RFI) emissions, and the term “electromagnetic” should be considered to refer generally to electromagnetic and radio frequencies.

During normal operation, many types of electronic equipment generate electromagnetic radiation in the form of electromagnetic fields and waves that can interfere with the operation of proximately located electronic equipment and wiring. Such electromagnetic radiation can propagate over a wide range of wavelengths and frequencies.

Electromagnetic shielding is used to reduce the electromagnetic field in a defined space by blocking the field with barriers made of conductive or magnetic materials. Electromagnetic shielding can reduce problems associated with the coupling of radio waves, electromagnetic fields, and electrostatic fields, for example, and can provide protection against interfering signals. Electromagnetic shielding made from conductive mesh or conductive tape is commonly applied to enclosures containing electrical devices in order to isolate the devices from the surrounding environment. Similarly, electromagnetic shielding made from conductive mesh or conductive tape is commonly applied to cables to isolate the cables from the environment through which the cables run.

### SUMMARY OF INVENTION

In general, the present invention relates to a method and apparatus for EMI protection. In an embodiment, the present invention is directed to an article of manufacture for electromagnetic interference shielding comprising a cylindrically-shaped sleeve constructed of a conductive fabric adapted to provide electromagnetic interference shielding by conducting at least a portion of electromagnetic interference shielding by either reflecting, absorbing, or conducting at least a portion of impinging electromagnetic radiation, wherein the cylindrically-shaped sleeve is made by rolling a piece of conductive fabric into a cylindrical shape such that opposing sides of the piece of conductive fabric are joined together resulting in the cylindrically-shaped sleeve having a seam at a junction of the opposing sides. In one embodiment, opposing sides of the piece of conductive fabric are sewn together. In another embodiment, the conductive fabric may comprise a single conductive material, a plurality of conductive materials, or a combination of at least one conductive material and at least one non-conductive material. In another embodiment, the combination of at least one conductive material and at least one non-conductive material comprises at least one conductive material intertwined with at least one non-conductive material.

### BRIEF DESCRIPTION OF THE DRAWINGS

FIG. 1 illustrates a longitudinal view of an exemplary conductive fabric sleeve in accordance with an embodiment;

FIG. 2 illustrates a longitudinal view of a cable within the exemplary conductive fabric sleeve of FIG. 1 in accordance with an embodiment;

FIG. 3 illustrates a cross-sectional view of the cable and conductive fabric sleeve of the embodiment of FIG. 2;

FIG. 4 illustrates a structure for electromagnetic interference protection using a conductive fabric sleeve in accordance with an embodiment; and

FIG. 5 illustrates a method for adding electromagnetic interference protection in accordance with an embodiment.

### DETAILED DESCRIPTION OF THE INVENTION

In general, the present invention relates to a method and apparatus for EMI protection, using a lightweight and flexible EMI shield, such as a pliable material (e.g., a fabric or cloth) which can produce attenuating effects by processes that include reflection, conduction, or absorption of a portion of the electromagnetic radiation to reflect and absorb a portion of electromagnetic radiation as electromagnetic fields and waves, thereby enhancing the performance of the EMI shield over a range of operational frequencies. The absorbent material may remove a portion of the electromagnetic radiation from the environment through power dissipation resulting from loss mechanisms. These losses mechanisms include reflective and abd absorptive losses in a dielectric material and conductive and restrictive losses in a conductive material having a finite conductivity.

One common example of electromagnetic shielding is the use of a conductive wire mesh to surround a conductive cable, such as a coaxial cable. The electromagnetic shielding impedes the escape of signals from the cable, and protects the cable against interfering signals in the environment. Another common technique used to protect conductive cables is to wrap the cable with a conductive tape. Conductive tapes typically include a layer of a conductive material, such as a conductive mesh or conductive fabric, attached to an adhesive layer.

It can be problematic or difficult to use existing conductive meshes and conductive tapes to protect wires or cables that must bend inside various compartments due to the physical layout of the space in which they are used. Conductive meshes and conductive tapes are not flexible or supple. In addition, conductive tape must be wrapped around wires and cables, and accordingly can be difficult and inconvenient to use. Further, the structural integrity of conductive tape sometimes fails when the tape loosens due to excessive bending of wires or if the initial tape wrapping is performed incorrectly. Also, the overall weight of the wiring or cables protected by existing conductive mesh or tape increases significantly and, thus, makes installation and use of the equipment containing such wiring less convenient and more expensive.

Accordingly, there is a need for a conductive shielding device that provides electromagnetic shielding for wires, cables, and other conductive devices, and which is flexible and lightweight and can be more easily used with wires and cables.

In one embodiment a lightweight and flexible EMI shield is provided, comprising a pliable material, such as a fabric or cloth, to reflect and absorb a portion of the electromagnetic radiation. The fabric can be manufactured, for example, by weaving, felting, braiding, or knitting natural or synthetic fibers and filaments. In an embodiment, a weave is formed by combining absorbent fibers or filaments with other fibers or filaments. For example, absorbent fibers may be combined in a weave together with conductive fibers. Yet other embodiments are possible in which the absorbent and conductive fibers are combined with other fibers or filaments, which may, for example, provide the EMI shield with other desirable attributes not directly related to EMI performance. For example, the other fibers may provide desired attributes of strength, moisture resistance, color, etc.

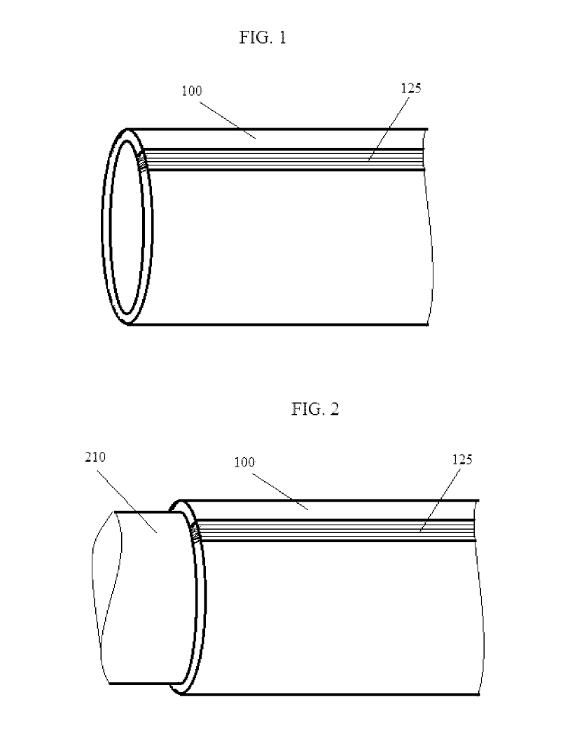

FIG. 1 illustrates a longitudinal view of an exemplary conductive fabric sleeve 100 in accordance with an embodiment. Conductive fabric sleeve 100 comprises a cylindrical sleeve constructed of a conductive fabric. In the illustrative embodiment, conductive fabric sleeve 100 is made by rolling a piece of conductive fabric into a cylindrical shape such that opposite sides of the piece are brought together, and sewing the opposite sides together. As a result, conductive fabric sleeve has a seam 125 at the junction of the opposing sides which were sewn together. In another embodiment, the opposite sides of the conductive fabric may be secured to one another in a number of ways, such as thermal press, conductive glue, Velcro®, and the like. In yet another embodiment, a conductive fabric can be braided to form a cylindrical shape resulting in a conductive fabric sleeve not having a seam.

It is to be understood that a conductive fabric is a fabric which can conduct electricity. A conductive fabric is typically made with metal strands woven into the construction of the fabric. In an embodiment, a conductive fabric may include a non-conductive or less-conductive substrate, which may be coated or embedded with electrically conductive elements, such as carbon, nickel, copper, gold, silver, titanium, etc. Substrates may include cotton polyester, nylon, and the like.

Conductive fabric sleeve 100 may be used to enclose any type of conducting wire or cable. For example, conductive fabric sleeve 100 may be used to enclose copper wire, twisted pair, coaxial cable, as well as a plurality of coaxial cables inside a single sleeve.

One skilled in the art will recognize that the list of substrates enclosed within the conductive fabric sleeve 100 is non-limiting and that multiple substrates may be combined in any way in various embodiments and may include any additional and/or desired components and/or configurations.

FIG. 2 illustrates a longitudinal view of a cable within the conductive fabric sleeve of FIG. 1 in accordance with an embodiment, where cable 210 is enclosed in conductive fabric sleeve 100 having seam 125. In an embodiment, cable 210 can be enclosed in the conductive fabric sleeve 100 during manufacturing of cable 210. In another embodiment, conductive fabric sleeve 100 may be manufactured separately and cable 210 can be inserted in conductive fabric sleeve 100 upon packaging or upon installation. It is to be understood that, although FIG. 2 illustrates a single cable enclosed in the conductive fabric sleeve, multiple cables may be enclosed in a single conductive fabric sleeve. Also, it is to be understood that, a conductive fabric material, identical to the fabric from which conductive fabric sleeve 100 is manufactured, may be layered between multiple cables enclosed in a common conductive fabric sleeve. In case of multiple cables being enclosed in a common conductive fabric sleeve, one or more hollow spaces between the multiple cables enclosed in the conductive fabric sleeve may be filled with a conductive material and/or substance for increased EMI shielding.

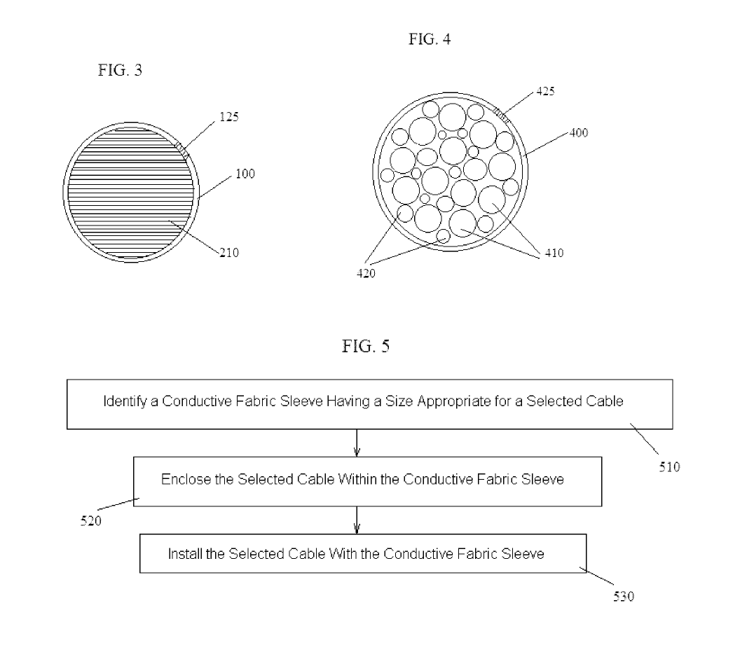

FIG. 3 illustrates a cross-sectional view of the cable and conductive fabric sleeve of the embodiment of FIG. 2, where cable 210 is enclosed in conductive fabric sleeve 100 having a seam 125. It is to be understood that, although FIG. 3 illustrates a single cable enclosed in the conductive fabric sleeve, multiple cables may be enclosed in a single conductive fabric sleeve. Also, it is to be understood that, a conductive fabric material, identical to the fabric from which the conductive fabric sleeve is manufactured, may be layered between the multiple cables enclosed in the conductive fabric sleeve. In another embodiment, one or more hollow spaces between multiple cables enclosed in the conductive fabric sleeve may be filled with a conductive material and/or substance for increased EMI shielding.

FIG. 4 illustrates a cross-sectional view of a plurality of cables 410 within a conductive fabric sleeve 400 having a seam 425. In the embodiment of FIG. 4, hollow spaces between the cables 410 are shown to be filled with a rolled conductive fabric 420 for improved EMI shielding of the multiple cables 410. As noted above, in an alternative embodiment, the hollow spaces between multiple cables 410 may be filled with a conductive material and/or substance, other than conductive fabric, for increased EMI shielding. One skilled in the art will recognize that enclosure of cables 410 and other conductive materials 420 within the conductive fabric sleeve 400 is non-limiting and may include any additional and/or desired components and/or configurations.

FIG. 5 illustrates a method for adding electromagnetic interference protection in accordance with an embodiment. The method of FIG. 5 may be utilized to implement an apparatus for EMI protection using the conductive fabric sleeve of FIG. 1 in accordance to an embodiment.

At step 510, a conductive fabric sleeve having a size commensurate with a selected cable is identified. It is to be understood that the size appropriate for the selected cable includes a length and a diameter of the selected cable.

At step 520, the selected cable is enclosed within the conductive fabric sleeve. It is to be understood that opposite sides of the conductive fabric sleeve may be brought together and fastened upon enclosing the selected cable within the conductive fabric sleeve.

Alternatively, opposite sides of the conductive fabric sleeve may be brought together and fastened prior to enclosing the selected cable within the conductive fabric sleeve. In this case, the opposite sides of the conductive fabric sleeve are brought together and fastened and then the conductive fabric sleeve is turned “inside out” prior to the selected cable being enclosed within the conductive fabric sleeve. The conductive fabric sleeve is turned “inside out” to ensure that a seam would not be entangled with adjacently installed cables, wires, or other sensitive equipment.

In another embodiment, in order to avoid having a seam, the conductive fabric sleeve may be manufactured by means of braiding of multiple fibers of one or more conductive materials to create the conductive fabric sleeve.

It is to be understood that a conductive fabric material may include a combination of conductive components made in a form of metal, alloy, plastic, foamed polymers, and other composite material threads/fibers of microscopic dimensions (measured in micrometers [1 μm equals to 0.0000001 meter] and/or nanometers [1 nm equals to 0.000000001 meter]) embedded within the conductive fabric to increase conductive characteristics of the conductive fabric sleeve while ensuring other essential non-EMI characteristics (flexibility, durability, and light weight).

In yet another embodiment, the composite fabric sleeve may be a composite of conductive and absorbent fabric materials. Generally, the resulting composite fabric sleeve includes a fabric composed of two or more constituent materials having different physical characteristics (e.g., a conductor and an absorber) in which each constituent fabric material retains its identity while contributing desirable properties to the whole. For example, a composite may include multiple layers and/or threads/fibers of each constituent material with distinct boundaries between each layer. Alternatively, a composite may include a single layer in which the constituent fabric materials are intermixed. In either case, the constituent structural material may include one or more of the constituent fabric materials embedded within a third fabric material.

At step 530, the selected cable, enclosed by the conductive fabric sleeve, is installed. It is to be understood that, the conductive fabric can be added to newly fabricated or existing cable packages, or housings, for electronic components, for EMI shielding purposes, by applying the conductive fabric to an absorbent EMI material and/or reflective EMI material. It is also to be understood that the conductive fabric sleeve may be installed such that it is in direct physical contact with the selected cable or is separated from the selected cable with one or more absorbent and/or conductive materials-layers, such as a metal foil, a conductive elastomer, paint, or plating additionally coated with an absorbent layer.

In an embodiment, the conductive fabric may include a high-frequency absorbent material (e.g., a lossy material). In some embodiments the lossy material is broadband in nature, absorbing EMI energy over a broad range of frequencies. The reflective EMI material can be any type of EMI shielding materials, such as sheet metal, currently used by those skilled in the art. One skilled in the art will recognize that examples of reflective EMI materials provided above is non-limiting and may include any additional and/or desired components and/or materials.

The foregoing Detailed Description is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

1. An article of manufacture for electromagnetic interference shielding comprising:
a cylindrically-shaped sleeve constructed of a conductive fabric adapted to provide electromagnetic interference shielding by conducting at least a portion of electromagnetic radiation, wherein the cylindrically-shaped sleeve is made by rolling a piece of conductive fabric into a cylindrical shape such that opposing sides of the piece of conductive fabric are joined together resulting in the cylindrically-shaped sleeve having a seam at a junction of the opposing sides which were sewn together.

2. The article of manufacture of claim 1, wherein the conductive fabric comprises a single conductive material.

3. The article of manufacture of claim 1, wherein the conductive fabric comprises a plurality of conductive materials.

4. The article of manufacture of claim 1, wherein the conductive fabric is a combination of at least one conductive material and at least one non-conductive material.

5. The article of manufacture of claim 4, wherein the combination of at least one conductive material and at least one non-conductive material comprises at least one conductive material intertwined with at least one non-conductive material.

6. The article of manufacture of claim 5, wherein the at least one conductive material comprises at least one of silver, nickel, copper, aluminum, steel, silver/glass, graphite, carbon, and conductive polymers.

7. The article of manufacture of claim 5, wherein the at least one non-conductive material comprises at least one of carbon-impregnated rubber, ferrite, iron, iron silicide, graphite, carbon in an organic-based carrier, and a paste composites.

8. The article of manufacture of claim 1, wherein opposing sides of the piece of conductive fabric are sewn together.

9. An apparatus for electromagnetic interference shielding comprising:
a cylindrically-shaped sleeve constructed of a conductive fabric adapted to provide electromagnetic interference shielding by conducting at least a portion of electromagnetic radiation.

10. The apparatus of claim 9, wherein the cylindrically-shaped sleeve is made by braiding fibers of the conductive fabric into a cylindrical shape.

11. A method for electromagnetic interference shielding:
identifying a cylindrically-shaped conductive fabric sleeve having a size commeasurable with a selected cable, wherein the cylindrically-shaped conductive fabric sleeve comprises a conductive fabric adapted to provide electromagnetic interference shielding by conducting at least a portion of electromagnetic radiation; and
enclosing the selected cable within the cylindrically-shaped conductive fabric sleeve.

12. The method of claim 11, wherein the conductive fabric comprises a single conductive material.

13. The method of claim 11, wherein the conductive fabric comprises a plurality of conductive materials.

14. The method of claim 11, wherein the conductive fabric is a combination of at least one conductive material and at least one non-conductive material.

15. The method of claim 14, wherein the combination of at least one conductive material and at least one non-conductive material comprises a plurality of fibers of at least one conductive material intertwined with a plurality of fibers of at least one non-conductive material.

16. The method of claim 15, wherein the at least one non-conductive material comprises at least one of carbon-impregnated rubber, ferrite, iron, iron silicide, graphite, carbon in an organic-based carrier, and a paste composites.

17. The method of claim 15, wherein the at least one non-conductive material comprises at least one of carbon-impregnated rubber, ferrite, iron, iron silicide, graphite, carbon in an organic-based carrier, and a paste composites.
